(19) United States
(12) Patent Application Publication
(10) Pub. No.: US 2026/0076149 A1
(43) Pub. Date: Mar. 12, 2026

(54) METHOD AND APPARATUS FOR MANUFATURING SOLAR PANELS

(71) Applicant: ADDFA CO., LTD., Cheonan-si (KR)

(72) Inventors: Jae Hun LEE, Cheonan-si (KR); Hyungjin PARK, Cheonan-si (KR); Sang Min LEE, Cheonan-si (KR); Hyun Cheol LEE, Cheonan-si (KR)

(21) Appl. No.: 19/321,643

(22) Filed: Sep. 8, 2025

(30) Foreign Application Priority Data
Sep. 6, 2024 (KR) 10-2024-0121914
Sep. 8, 2025 (KR) 10-2025-0127632

(51) Int. Cl. H01L 21/66; H01L 21/677; H01L 21/68; H10F 19/90; H10F 71/00

(52) U.S. Cl. CPC H10P 74/232; H10F 19/904; H10F 71/134; H10P 72/3306; H10P 72/53

(57) ABSTRACT

Described are a solar panel manufacturing method and apparatus. The manufacturing method comprises: placing a first sheet on a glass substrate; arranging a plurality of cell strings on the first sheet placed on the glass substrate; performing an inspection for the arranged plurality of cell strings to detect a defective cell string; replacing the defective cell string with a new cell string when the defective cell string is detected; and joining bus bars for electrically connecting the plurality of cell strings, and sequentially placing a second sheet and a backsheet.

### CROSS-REFERENCE TO RELATED APPLICATION

This application claims the benefit of Korean Patent Application No. 10-2024-0121914, filed on Sep. 6, 2024, and Korean Patent Application No. 10-2025-0127632, filed on Sep. 8, 2025, which are hereby incorporated by reference in their entirety.

### BACKGROUND

### 1. Technical Field

The embodiments disclosed in the present specification relate to a solar panel manufacturing method and apparatus, and more particularly, to a solar panel manufacturing method and apparatus for improving manufacturing efficiency of a solar panel and minimizing a defect rate by detecting and replacing a defective cell string in advance during solar panel manufacturing.

### 2. Description of the Related Art

Recently, the use of fossil fuel-based energy has been pointed out as a main cause of environmental pollution and greenhouse gas emissions worldwide. Accordingly, efforts are actively being made to reduce the use of non-environmentally friendly energy sources such as thermal power generation or petroleum fuel, and to replace them with renewable and environmentally friendly energy sources such as solar energy, wind energy, and hydrogen energy. Among them, solar power generation has been widely disseminated due to the advantage of directly producing electricity through solar panels, and accordingly, research and industrial demand for manufacturing technology of solar panels are continuously increasing.

In a conventional solar panel manufacturing process, after forming a cell string in which solar cells for producing electricity are connected in series, the cell string is placed on a panel substrate to produce a module. However, in this process, defects may occur depending on the quality of the cell or the connection state, and therefore, inspection for defect detection is performed at the cell string stage. In addition, even after completing a panel by placing the cell strings, a separate defect detection process is performed again. As such, since defect detection is repeatedly performed multiple times during the manufacturing process, there have been problems in that process efficiency is lowered, manufacturing delay occurs, and inconvenience of workers is caused.

In some manufacturing processes, after placing the cell strings on a substrate and placing a second sheet, an Electroluminescence (EL) inspection is performed to check electrical characteristics. However, in this case, if a defect is found during the inspection, the second sheet placed must be separated again and the defective cell string must be replaced. Such a process may cause a risk of breaking the alignment state of the cell strings, and excessive manual work is required for the replacement work, thereby reducing productivity.

Furthermore, the repetitive and inefficient defect detection and replacement process as described above complicates the entire manufacturing process, may impair the stability of subsequent processes such as lamination, and consequently involves various problems of reducing a yield rate.

Accordingly, there is a need for a solar panel manufacturing method capable of improving efficiency of solar panel manufacturing while minimizing a defect rate, and facilitating recycling of defective cell strings.

In relation to this, Korean Registered Patent No. 10-1134085 discloses a pre-working manufacturing process of a solar cell module. Specifically, the prior art document describes a process of placing EVA on glass, arranging strings in which a plurality of solar cells are connected in series by conductor ribbons at regular intervals, connecting protruding ribbons at ends of the plurality of strings by soldering, and then sequentially placing EVA and a backsheet thereon to form a semi-finished module. It is further described that an EL test is performed on the semi-finished module. According to such prior art, since the EL test is performed after electrically connecting the cell strings and placing EVA and the backsheet thereon, the above-mentioned problems, that is, breaking the alignment state of the cell strings, lowering productivity due to excessive manual work required for replacement work, complicating the entire manufacturing process, impairing the stability of subsequent processes, and consequently reducing a yield rate, are caused.

Therefore, there has been a need for a technology for solving the above-mentioned problems.

Meanwhile, the foregoing background art is technical information that the inventor possessed for deriving the present invention or that was acquired during the process of deriving the present invention, and it cannot necessarily be regarded as publicly known technology disclosed to the general public before the filing of the present invention.

### SUMMARY

The embodiments disclosed in the present specification were devised to solve the problems of the prior art as described above.

The embodiments disclosed in the present specification are intended to eliminate process delay and inconvenience of workers caused by repeated defect detection performed multiple times during the manufacturing process.

In addition, the embodiments disclosed in the present specification are intended to reduce damage of strings, instability of string alignment, and excessive dependence on manual work, which occur in a process of separating welded bus bars and placed sheets and replacing defective cell strings, by performing defect detection of cell strings before placing a second sheet and replacing defective cell strings.

Furthermore, the embodiments disclosed in the present specification aim to improve efficiency of solar panel manufacturing, enhance productivity, and secure uniform quality by solving problems that the entire manufacturing process becomes complicated and a yield rate is reduced due to unreasonable inspection and replacement procedures of the prior art.

The embodiments disclosed in the present specification are also intended to minimize damage of cell strings in a process of separating defective cell strings, repair them, and minimize an amount of wasted materials.

Moreover, the embodiments disclosed in the present specification are intended to provide a solar panel manufacturing method and apparatus capable of not only rearranging the entire strings but also reusing repaired cell strings by inputting them again when replacing defective cell strings.

According to one embodiment, a solar panel manufacturing method comprises: placing a first sheet on a glass substrate; arranging a plurality of cell strings on the first sheet placed on the glass substrate; performing an inspection for the arranged plurality of cell strings to detect a defective cell string; replacing the defective cell string with a new cell string when the defective cell string is detected; and joining bus bars for electrically connecting the plurality of cell strings, and sequentially placing a second sheet and a backsheet.

In this case, the replacing the defective cell string with a new cell string comprises: removing the defective cell string; performing a foreign substance inspection on an area from which the defective cell string has been removed; and arranging the new cell string in the area from which the defective cell string has been removed when no foreign substance is detected.

And the detecting the defective cell string comprises performing an Electroluminescence (EL) inspection for the arranged plurality of cell strings, and the removing the defective cell string to the arranging the new cell string may be performed based on machine vision. However, a visual inspection may be secondarily performed for the EL inspection. In addition, the removing the defective cell string to the arranging the new cell string may also be selectively performed manually.

Here, the new cell string is a normal cell string in which no defect is detected in a pre-inspection at a string unit, and after the replacing with the new cell string, sequentially placing the second sheet and the backsheet on the plurality of cell strings may be performed.

Alternatively, after the replacing with the new cell string, the detecting the defective cell string may be performed again.

Meanwhile, the solar panel manufacturing method further comprises repairing the defective cell string removed in the removing the defective cell string, wherein the repairing comprises: heating an electrode portion of a defective cell included in the defective cell string to release a connection between the electrode of the defective cell and wiring; cutting the wiring whose connection with the electrode is released to separate the defective cell from the defective cell string; replacing the separated defective cell with a replacement cell; and joining wiring between the replacement cell and an adjacent cell to electrically connect them to form a string.

Here, the replacing comprises inputting the cell string repaired in the repairing as the new cell string.

And the detecting the defective cell string comprises detecting a position of the defective cell included in the defective cell string, and the repairing may be performed with reference to the position of the defective cell detected in the detecting the defective cell string.

Meanwhile, a solar panel manufacturing apparatus for performing the solar panel manufacturing method comprises a vision align apparatus which performs the detecting the defective cell string and includes a vision align stage and a vision align robot, wherein the vision align stage comprises: a conveyor belt that supports and transfers a panel in which the plurality of cell strings are arranged; a plurality of pulleys which are arranged to cross up and down to transfer the conveyor belt such that a section in which the conveyor belt supports the panel and a section in which the conveyor belt is spaced downward and does not support the panel are alternately formed; and a backlight disposed in the section in which the conveyor belt is spaced downward and does not support the panel, to irradiate light upward from a lower surface of the panel.

Here, the solar panel manufacturing apparatus comprises an information processing device that detects the defective cell string by analyzing an image captured by performing EL inspection, wherein the vision align robot comprises: a robot arm that removes the defective cell string from the panel based on position information of the defective cell string received from the information processing device, and arranges a new cell string in an area from which the defective cell string has been removed; and a vision camera module that captures the panel and detects a position of the plurality of cell strings arranged on the panel.

According to any one of the above-mentioned means for solving the tasks, process delay and inconvenience of workers caused by repeated defect detection performed multiple times during the manufacturing process can be eliminated, and the production cost of products can be reduced by minimizing manual work.

In addition, according to any one of the above-mentioned means for solving the tasks, by performing defect detection of cell strings before placing a second sheet and replacing defective cell strings, it is possible to reduce damage of strings, instability of string alignment, and excessive dependence on manual work, which occur in a process of separating welded bus bars and placed sheets and replacing defective cell strings.

Furthermore, according to any one of the above-mentioned means for solving the tasks, it is possible to improve efficiency of solar panel manufacturing, enhance productivity, and secure uniform quality by solving problems that the entire manufacturing process becomes complicated and a yield rate is reduced due to unreasonable inspection and replacement procedures of the prior art.

And according to any one of the above-mentioned means for solving the tasks, it is possible to minimize an amount of wasted materials by minimizing damage of cell strings in a process of separating defective cell strings and repairing them.

Moreover, according to any one of the above-mentioned means for solving the tasks, in replacing defective cell strings, not only the replaced cell strings but also the entire strings can be rearranged, and repaired cell strings can be input again to be reused, thereby providing a solar panel manufacturing method and apparatus.

Furthermore, according to any one of the above-mentioned means for solving the tasks, since replacement and repair of defective cell strings are easy and rearrangement of the entire cell strings is possible, there is an advantage of good flexibility in applying to a production line and arranging equipment.

The effects obtainable in the disclosed embodiments are not limited to the effects mentioned above, and other effects not mentioned can be clearly understood by those skilled in the art to which the disclosed embodiments belong from the following description.

### BRIEF DESCRIPTION OF THE DRAWINGS

The above and other objects, features, and advantages of the present invention will be more clearly understood from the following detailed description taken in conjunction with the accompanying drawings, in which:

FIG. 1 illustrates a conceptual diagram schematically showing a conventional solar panel manufacturing process.

FIG. 2 illustrates a flowchart sequentially showing a solar panel manufacturing method according to an embodiment.

FIG. 3 illustrates a conceptual diagram schematically showing a solar panel manufacturing method according to an embodiment illustrated in FIG. 2.

FIG. 4 illustrates a partial flowchart for more specifically explaining step S209 in the solar panel manufacturing method according to an embodiment illustrated in FIG. 2.

FIG. 5 illustrates an example of a production line layout according to a solar panel manufacturing method of an embodiment.

FIGS. 6 and 7 illustrate examples of a vision align equipment applied to the production line illustrated in FIG. 5.

FIG. 8 illustrates an example of a production line layout according to a solar panel manufacturing method of another embodiment.

FIG. 9 illustrates a cell string supply equipment applied to a production line according to a solar panel manufacturing method of the embodiment illustrated in FIG. 5 or the other embodiment illustrated in FIG. 8.

FIG. 10 illustrates an example of a production line layout according to a solar panel manufacturing method of still another embodiment.

### DETAILED DESCRIPTION

Hereinafter, various embodiments will be described in detail with reference to the accompanying drawings. The embodiments described below may be implemented in various different forms. In order to clearly explain the features of the embodiments, detailed description of matters widely known to those skilled in the art to which the embodiments belong is omitted. In the drawings, portions irrelevant to the description of embodiments are omitted, and like reference numerals denote like parts throughout the specification.

In the entire specification, when a component is described as being “connected” to another component, this includes not only “directly connected” but also cases in which “another component is interposed therebetween.” In addition, when a component is described as “including” another component, this means that, unless specifically stated otherwise, it does not exclude other components but may further include other components.

The embodiments will now be described in detail with reference to the accompanying drawings.

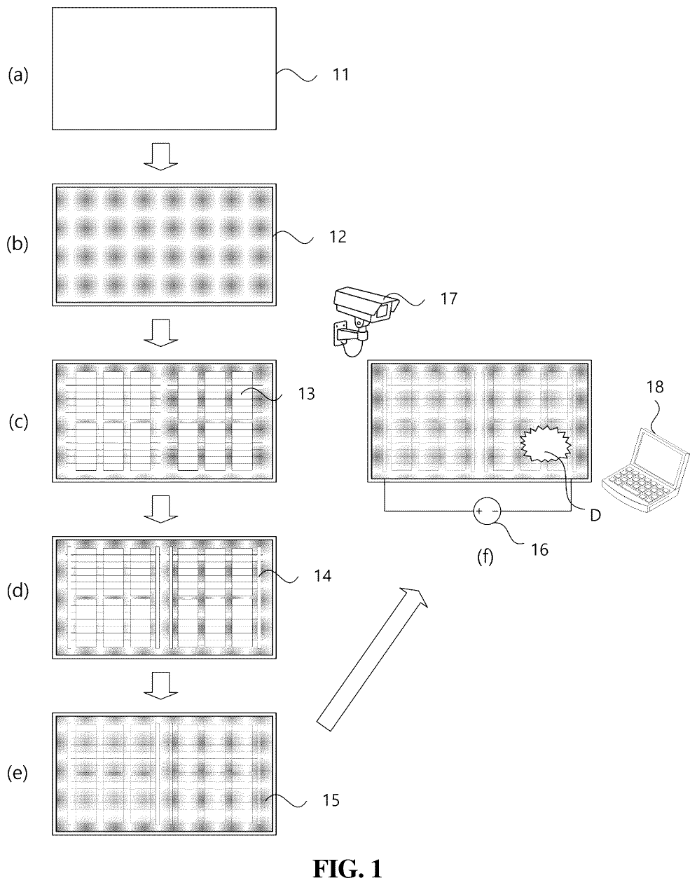

FIG. 1 illustrates a flowchart sequentially showing a conventional solar panel manufacturing process. Referring to FIG. 1, the conventional process is performed as follows. First, in FIGS. 1(a) and 1(b), a first sheet 12 is placed on an upper surface of glass substrate 11 used as a substrate of a solar panel. The first sheet 12 is generally made of a thermoplastic resin such as EVA (Ethylene-Vinyl Acetate) and functions as an adhesive layer and an insulating layer between the glass substrate 11 and solar cells to be placed thereon. This placing process may include aligning and pressing the sheet uniformly to prevent bubbles.

Next, in FIG. 1(c), a cell string 13 in which a plurality of solar cells are connected in series is placed on the first sheet 12. Each cell string 13 is electrically connected between cell electrodes through ribbon wires and is arranged at predetermined intervals and orientations on the substrate.

Then, in FIG. 1(d), a bus bar 14 is joined to electrically connect the arranged cell strings 13 with each other. The bus bar 14 is formed of copper ribbons, and is joined to terminals of the cell strings by soldering or hot bar bonding. The joining process should be precisely performed to minimize electrical resistance and secure mechanical reliability.

Next, in FIG. 1(e), a second sheet 15 is placed on the cell strings 13 and the bus bars 14. The second sheet 15 is generally made of a transparent sheet similar to the first sheet 12, and a backsheet may be further placed. The second sheet 15 and the backsheet protect the cell strings 13 from external environments and provide mechanical stability. When placing, rollers or presses may be used to closely adhere the sheet to the cell surface, and care must be taken to prevent foreign substances or wrinkles.

Thereafter, in FIG. 1(f), while the panel placed up to the second sheet 15 is accommodated in a dark room, a power supply device 16 applies current to the cell strings 13. When current is applied, each solar cell emits light, and the emission occurs in the infrared region. Accordingly, the emitting cell strings 13 are captured by an infrared camera 17, and the captured image is transmitted to an information processing device 18. The information processing device 18 analyzes the image data to determine whether there are defects such as cracks, soldering defects, or shorts in the cell strings 13. This process is called Electroluminescence (EL) inspection, and is widely used as a quality inspection means in solar panel manufacturing.

However, since the bus bars 14 are soldered or hot bar bonded in step (d) and the second sheet 15 is placed in step (e), the EL inspection of step (f) is performed after that. Therefore, if a defective cell string 13 is detected in the inspection, the bus bars 14 and the placed second sheet 15 must be removed again. This removal is difficult to perform by a simple machine operation, and workers often have to manually peel off the sheet. In addition, in the process of replacing the defective cell string 13, the alignment state of adjacent cell strings 13 may be broken, and after re-placing a new cell string, the bus bar 14 must be joined again. This causes delay of process time, reduction of yield, and an increased burden on workers.

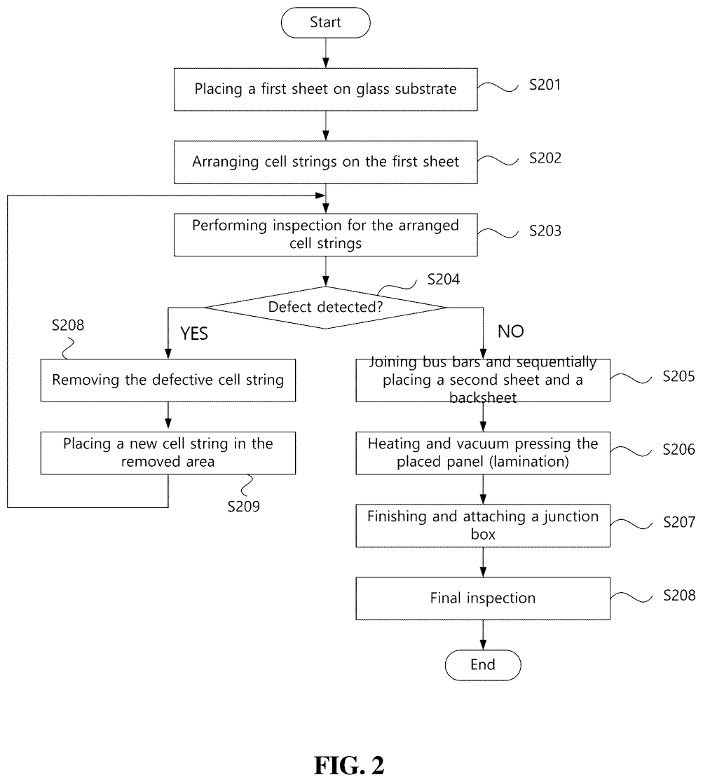

Accordingly, in a solar panel manufacturing method according to an embodiment, while solving the above problems, process time is shortened, wasted materials are minimized, and inspection efficiency is improved, so that a solar panel is manufactured according to a method as illustrated in FIG. 2.

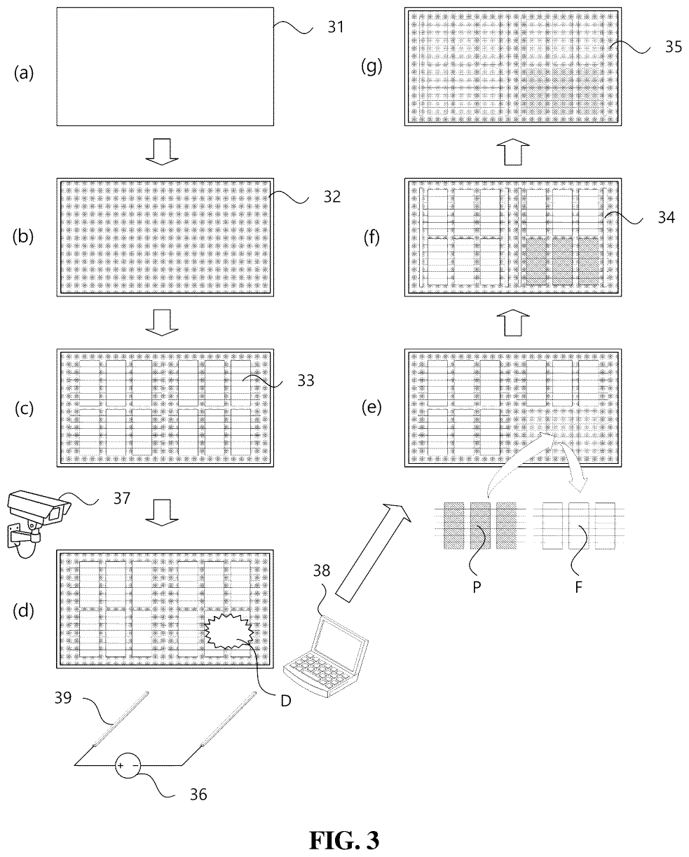

FIG. 2 illustrates a flowchart sequentially showing a solar panel manufacturing method according to an embodiment, and FIG. 3 illustrates a conceptual diagram schematically showing a solar panel manufacturing method according to an embodiment illustrated in FIG. 2. Referring to FIGS. 2 and 3, a solar panel manufacturing method according to an embodiment includes the following processes.

First, a first sheet 32 is placed on an upper surface of glass substrate 31 used as a substrate of a solar panel (S201). As illustrated in FIG. 3(a), the glass substrate 31 is prepared, and then in FIG. 3(b), the first sheet 32 is placed on the upper surface of the glass substrate 31. The first sheet 32 is generally formed of an EVA (Ethylene-Vinyl Acetate) or POE (Polyolefin Elastomer) sheet, and after being supplied in a roll-to-roll manner and cut, is placed on the glass substrate 31 by vacuum adsorption or a roller press. The process may further include preheating by a heating plate or removing static electricity to prevent bubbles between the first sheet 32 and the glass substrate 31.

Next, as illustrated in FIG. 3(c), a cell string 33 in which a plurality of solar cells are connected in series is arranged on the first sheet 32 (S202). The cell string 33 is pre-manufactured by a tabber and a stringer, and may be precisely positioned and placed on the first sheet 32 by a vision align apparatus. During arrangement, the spacing between cells may be maintained uniformly by an automatic guide or a suction-type robot gripper.

Then, a step (S203) of detecting defects of the arranged cell strings 33 is performed. According to one embodiment, defect detection may be performed by an EL inspection. Referring to FIG. 3(d), in step S203, the panel manufactured up to that stage is accommodated in a dark room, and a predetermined DC current is applied to the cell strings 33 through a power supply device 36. When each cell emits light, an emission pattern is captured by an infrared camera 37, and the captured emission pattern is analyzed by an information processing device 38. In this process, the information processing device 38 may analyze the image data to detect micro cracks inside cells, connection defects between cells, soldering defects, and the like. However, step S203 may also be performed by another inspection method such as visual inspection. For example, a worker may detect cracks or disconnections with the naked eye and mark the defect location on the panel. Alternatively, other inspection methods may also be used to detect defective cell strings. Visual inspection may be used as an auxiliary method when EL inspection cannot be performed, such as when equipment fails, and accordingly, the production line may be designed to branch into an EL inspection line and a manual visual inspection line.

In the case of performing EL inspection, a temporary bus bar 39 may be connected to the power supply device 36. The temporary bus bar 39 is a member for temporarily electrically connecting terminals of each cell string 33, and unlike the bus bar 34 fixed to the cell strings 33, it is not permanently soldered but is a reversible connection member provided only for supplying power in the inspection step. For example, the temporary bus bar 39 may have a structure in which a plurality of spring pins (pogo pins) are provided on one surface of a bar and elastically pressed to form an electrical connection with the terminals of the cell strings 33. In this case, current can be applied only by contact without mechanical coupling, and can be easily released after completion of the inspection.

Alternatively, the temporary bus bar 39 may have a magnetic clamp structure, in which a magnetic member is provided at a portion contacting the terminal of the cell string 33, so that the conductive terminal of the cell string 33 is attracted and connected by magnetic force. This method allows easy repetitive connection/disconnection and maintains stable contact resistance.

Further, the temporary bus bar 39 may have a comb bar type structure, in which a plurality of ribbon-shaped contact portions are arranged in a comb shape, and the lead terminals of the cell strings 33 are seated thereon to be electrically connected. This structure is simple, and even if there is a slight misalignment in the cell string arrangement position, contact can still be achieved.

As described above, the temporary bus bar 39 is temporarily electrically connected only during the inspection with the power supply device 36, and applies a predetermined DC current so that the cell strings 33 emit light. The emission pattern is captured by the infrared camera 37 as described above and is analyzed by the information processing device 38.

In step S204, it is determined whether a defect is detected as a result of the inspection performed in step S203. If it is determined that no defect is present in the arranged cell strings 33, bus bars 34 are joined to the terminals of the cell strings 33, and then a second sheet 35 and a backsheet are sequentially placed on the cell strings 33 (S205). Referring to FIGS. 3(f) and 3(g), bus bars 34 are joined to the panel with cell strings 33 arranged after all inspections are completed, and the second sheet 35 and the backsheet are placed thereon. The second sheet 35 is mainly an EVA sheet, and the backsheet is an opaque PET/fluorine-based laminated film. Subsequently, the placed panel is input into a laminator to undergo a heating and vacuum pressing process (S206). At this time, a pressure vacuum state is maintained for several minutes at about 150° C., and the EVA resin is melted and cured so that the cells and sheets are completely adhered. Thereafter, finishing processes such as attaching a junction box, frame mounting, and electrical termination are performed (S207).

On the other hand, if a defective cell string 33 is detected in step S204, as illustrated in FIG. 3(e), the defective cell string 33 is removed (S208). The removal process may be performed by a suction-type robot handler or manually, and after releasing the connection from the temporary bus bar 39, the defective cell string is lifted out. Thereafter, a new cell string 33 is placed in the area from which the defective cell string has been removed (S209). At this time, a vision align apparatus may also correct the placement position. The cell string 33 to be replaced may be a normal cell string already inspected, but if not, the panel manufactured up to that stage may be connected again to the temporary bus bar 39, and EL inspection may be performed again to confirm that it is in a normal state before proceeding.

Steps S208 to S209 may be performed based on machine vision by a vision align apparatus as described above. However, depending on the embodiment, they may also be performed manually by a worker. In the case of manual work, a separate workstation is required, so the production line may be designed to branch into a vision align apparatus line and a manual work line. Accordingly, when the vision align apparatus is available, the solar panel being produced is transferred to the vision align apparatus, and in special cases such as failure or throughput saturation of the vision align apparatus, at least some solar panels may be selectively transferred to a manual work line.

Accordingly, when all defective cell strings 33 are removed and normal cell strings 33 are placed in the solar panel, steps S205 to S207 are sequentially performed to complete the solar panel.

According to this, even without pre-inspecting each unit cell string individually, defective cell strings can be easily detected and removed, and since a plurality of cell strings can be inspected at once, inspection time and cost can be reduced. In addition, since bus bars or sheets already fixed are not required to be removed in the process of replacing defective cell strings, problems of generating additional defects during replacement are also solved.

In particular, according to the solar panel manufacturing method described above, even if the repetitive EL inspection process in which EL inspection is performed for each cell string after stringing and then again for the entire panel after placing a second sheet or backsheet is shortened to a single step, quality of the solar panel can be maintained.

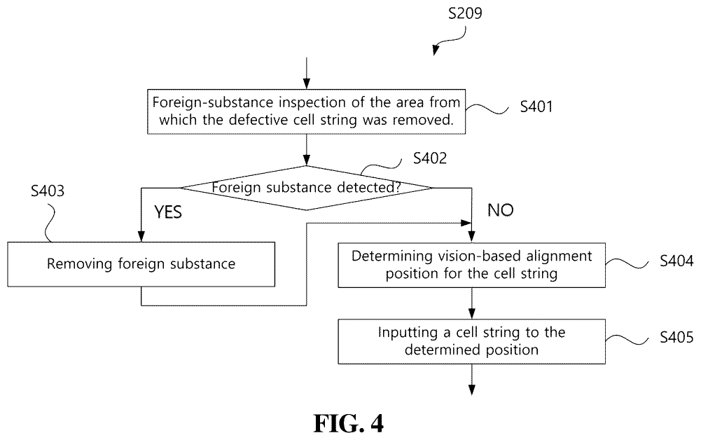

Meanwhile, step S209 of FIG. 2 may include detailed steps as illustrated in FIG. 4. FIG. 4 illustrates a partial flowchart for more specifically explaining step S209 in the solar panel manufacturing method according to an embodiment illustrated in FIG. 2.

As illustrated in FIG. 4, in the process of placing a new cell string in an area from which a defective cell string has been removed in step S209, first, a step S401 of performing a foreign substance inspection on the area from which the defective cell string has been removed is performed. The foreign substance inspection may be performed by machine vision of the vision align apparatus described above, or visually by a worker depending on the embodiment. This is a procedure to prevent poor adhesion or electrical connection failure in subsequent placement of a cell string.

Next, in step S402, existence and position of foreign substances are detected based on the inspection result of step S401. If foreign substances are detected in step S402, they are removed using a suction device, a brush, a static electricity removing device, or manual work by a worker (S403). After removal of the foreign substances, the process proceeds to the next step.

If it is determined that no foreign substance exists, or detected foreign substances have been removed, an alignment position of a new cell string to be placed is determined in the area from which the defective cell string has been removed (S404). Specifically, reference marks on the substrate or positions of adjacent cell strings may be recognized by a camera image, and a target placement coordinate of the new cell string may be calculated.

Subsequently, the new cell string is input and placed at the calculated target placement coordinate (S405). During this process, the position of the cell string to be newly input may be corrected in real time depending on inclination, overlap with adjacent cell strings, or spacing. Of course, input of the new cell string may also be performed manually by a worker, or separately performed by a cell string lay-up device rather than the vision align apparatus.

In step S405, the new cell string to be input may be a cell string judged as normal in a pre-inspection performed at a string unit. However, in another embodiment in which the new cell string to be input is not pre-inspected, after the new cell string is placed, EL inspection may be performed again for the entire solar panel as described above with reference to FIG. 2. In this case, EL inspection at the panel level may be performed repeatedly, and even if two or more defective cell strings are detected, after all defective cell strings are removed and new cell strings are placed, EL inspection may be performed again for the solar panel.

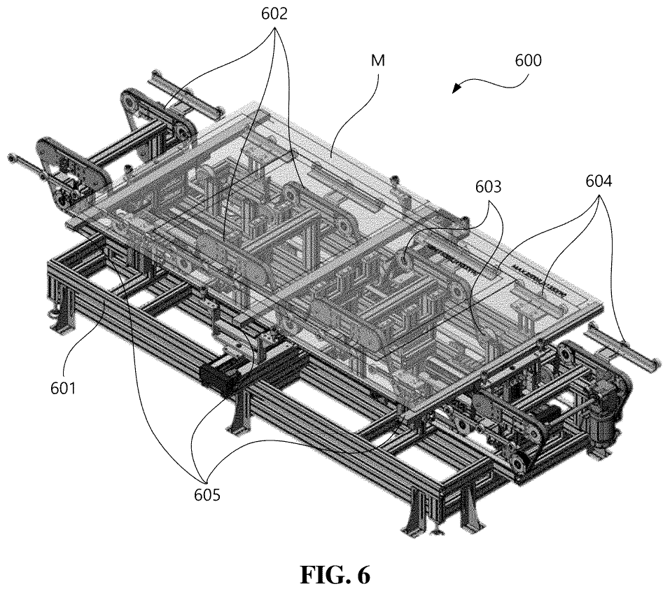

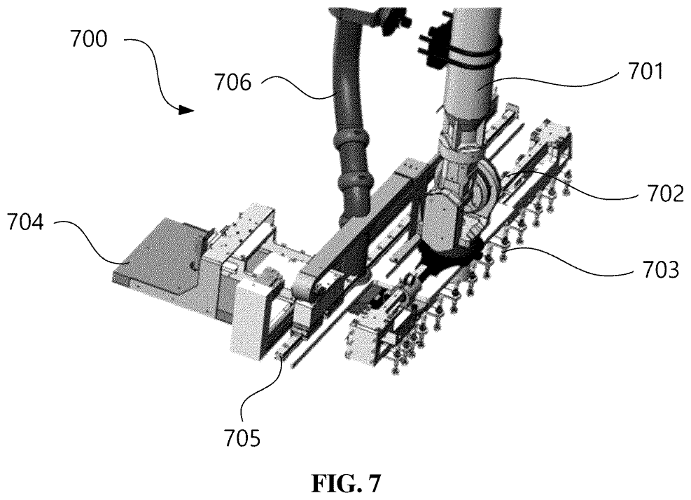

Meanwhile, in step S209 described with reference to FIG. 4, a vision align apparatus illustrated in FIGS. 6 and 7 may be used. The vision align apparatus may include a vision align stage 600 illustrated in FIG. 6 and a vision align robot 700 illustrated in FIG. 7.

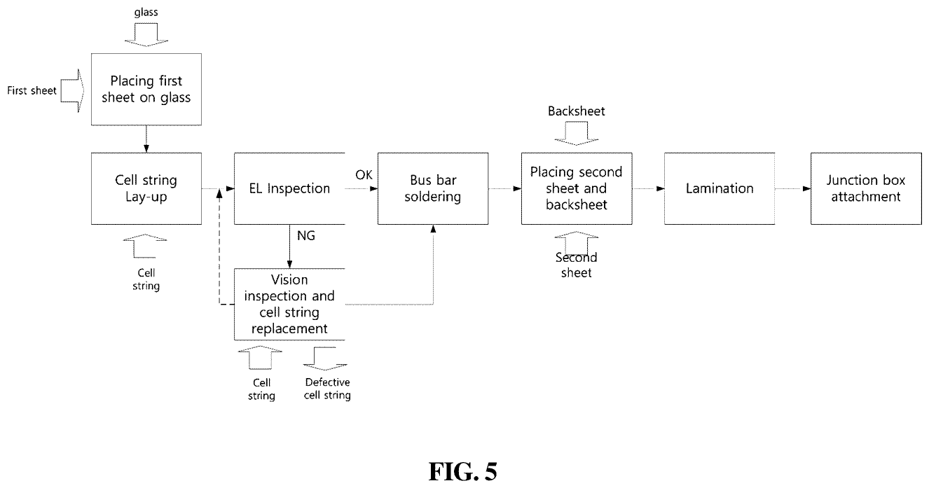

Hereinafter, a production line necessary for implementing the solar panel manufacturing method described above with reference to FIGS. 2 and 4 will be described. FIG. 5 illustrates an example of a production line layout according to a solar panel manufacturing method of an embodiment. In FIG. 5, each block represents a process performed on the production line rather than production equipment itself, and the blocks are arranged according to an order in which each process is performed on the production line. In addition, materials required for performing each process or materials discharged by performing the process are indicated by arrows.

Referring to FIG. 5, a solar panel manufacturing apparatus according to an embodiment of the present invention is configured as a production line for continuously performing a panel manufacturing process, and while a solar panel is transferred by a conveyor belt, the overall process is performed, and the production line may be branched into a normal flow and a correction flow according to a determination result in an EL inspection step.

First, at the front end of the line, a tempered glass and first sheet placing block is provided. In this section, a tempered glass input device, a first sheet supply device, and a sheet placing device including a roller press or a vacuum adsorber are arranged. The devices place the first sheet uniformly on an upper surface of the tempered glass so that bubbles or wrinkles do not occur.

Thereafter, in a cell string lay-up block, a cell string automatic supply device and a robot handler may be arranged. Cell strings are manufactured and supplied by a stringer device, and may be arranged on the first sheet by a vision align apparatus.

A next step is an EL inspection block, and a temporary bus bar connection device, a power supply device, an infrared camera, and an information processing device may be provided. In this section, current is applied to the arranged cell strings to induce emission, an infrared camera captures an emission image, and the information processing device determines whether a defect is present. However, as described above, the inspection method is not necessarily the EL inspection, and another inspection may be performed depending on equipment provided on the production line.

When no defect is detected, the solar panel proceeds to a bus bar soldering block. In this section, a bus bar supply device and a soldering device (soldering iron, hot bar bonder, or laser soldering device) are arranged, and terminals of the cell strings and bus bars are electrically joined.

Subsequently, the solar panel is transferred to a second sheet and backsheet placing block, in which a second sheet supply device, a backsheet supply device, and a sheet-placing roller press are provided.

Thereafter, in a lamination block, a laminator is arranged, and the panel undergoes a heating and vacuum pressing process to be integrated.

Finally, in a junction box attaching block, a junction box attaching device and an insulator applying device are provided, and electrical termination processing is performed.

On the other hand, when a defect is detected in the EL inspection block, the panel is branched to a vision inspection and cell string replacement block. In this section, a vision align apparatus, a foreign substance removing device (brush, suction device, static electricity remover), and a cell string supply device may be provided. Accordingly, in the vision inspection and cell string replacement block, a defective cell string is removed from the solar panel, a placement position of a replacement cell string is determined through vision alignment, and a new cell string is input. A panel for which replacement has been completed merges again into the bus bar soldering block and proceeds in the same manner as the subsequent processes.

Meanwhile, in the vision inspection and cell string replacement block, when the supplied cell string has undergone various inspections such as EL inspection at a string unit before being supplied, as described above, a panel for which replacement of the defective cell string has been completed may merge into a normal flow and be supplied to the bus bar soldering block. On the other hand, when a cell string that has not undergone EL inspection at a string unit is supplied in the vision inspection and cell string replacement block, as indicated by dotted lines in FIG. 5, the panel for which replacement of the defective cell string has been completed may be returned again to the EL inspection block, and EL inspection at a panel unit may be performed again.

Meanwhile, when the vision align apparatus used in the vision inspection and cell string replacement block is viewed in more detail, it may include a vision align stage 600 illustrated in FIG. 6 and a vision align robot 700 illustrated in FIG. 7.

Here, the vision align stage 600 is disposed on the production line of FIG. 5, and allows replacement or rearrangement of cell strings while transferring the solar panel.

The vision align stage 600 may be installed based on a base 601. The base 601 serves as a structural support to stably support a conveyor belt 602, pulleys 603, guide rollers 604, and a backlight 605. Specifically, the base 601 is formed in a metal frame or a cast frame structure, and thick steel plates or aluminum profiles are mainly used to secure rigidity of the whole apparatus. On an upper portion of the base 601, shaft supports for fixing the conveyor belt 602 and the pulleys 603 are provided, and on a lower portion, support legs for vibration absorption and leveling bolts may be mounted.

Meanwhile, on the base 601, a conveyor belt 602 for transferring a panel is provided. The conveyor belt 602 circulates while maintaining tension by a plurality of pulleys 603 supported by the base 601, and transfers the solar panel on the vision align stage 600.

The conveyor belt 602 is formed of a synthetic resin or rubber material excellent in heat resistance and wear resistance, and has sufficient strength to stably support a load of the solar panel. In addition, to prevent surface scratches during panel transfer, an upper surface is processed to be flat and have a low friction coefficient. In some embodiments, a fine uneven pattern or a coating layer may be formed on a belt surface to prevent shaking of the panel.

The conveyor belt 602 is mounted in a closed loop by a plurality of pulleys 603 such as a driving pulley and a driven pulley, and moves at a constant speed by rotation of a motor. A transfer speed may be precisely controlled by servo motor and inverter control, and when vision alignment inspection is required, immediate stop or low-speed operation is possible.

Particularly, the conveyor belt 602 of the present embodiment is configured such that, by arrangement and rotation of the pulleys 603, in a certain section the conveyor belt 602 forms an upper panel transfer surface to transfer the solar panel, and in another section the conveyor belt rotates at a position spaced downward by a predetermined distance from the upper panel transfer surface. Through this, a space where the backlight 605 to be described later may be installed can be provided in a section where the conveyor belt 602 is cut off in the upper transfer surface.

The pulleys 603 are rotating members for guiding the conveyor belt 602 and maintaining tension, and are rotatably supported on the base 601. In a general conveyor device, pulleys merely drive a belt or change a direction, but the pulleys 603 of the present embodiment additionally perform a function of spacing the conveyor belt downward from the transfer surface in a certain section.

Specifically, the pulleys 603 may be divided into a driving pulley and a driven pulley, the driving pulley circulates the belt by being connected to a motor, and the driven pulley supports an opposite end of the belt and maintains tension. Shafts of these pulleys are installed on the base 601 via bearings to allow low-friction rotation.

A plurality of pulleys 603 are arranged to cross up and down so that the conveyor belt 602 moves along a path in a zigzag form, that is, crossing up and down.

When the pulleys 603 are arranged as described above, on an upper transfer surface of the conveyor belt 602, a section supporting the panel and a section in which the belt is spaced downward and no support is performed are alternately formed. That is, when viewed from above, the conveyor belt does not form a continuous surface, and openings are formed at predetermined intervals. A backlight 605 is disposed below the openings, and light can be irradiated upward from a lower surface of the panel through this section.

In addition, guide rollers 604 are provided on both sides of the conveyor belt 602 to prevent sagging or shaking of the panel during transfer. The guide rollers 604 are rotatably disposed on both edges or a lower side of the conveyor belt 602 and are formed as freely rotating cylinders. Surfaces of the rollers are coated with a synthetic resin or rubber excellent in wear resistance so that damage or scratches do not occur even when contacting an edge or a lower surface of the panel. When the panel moves on the conveyor belt 602, the guide rollers 604 guide a position of the panel along side surfaces of the belt to perform an alignment maintenance function so that a transfer path is not deviated. In addition, even when the belt slightly sags due to weight of the panel, the guide rollers 604 support it from below to maintain a flat transfer surface.

Meanwhile, the backlight 605 is an illumination device disposed below the solar panel in the vision align stage 600 to provide light transmitted through the solar panel so that an alignment state and defects of the cell strings can be detected by vision inspection.

Specifically, the backlight 605 is formed as an LED array or a planar light source module, and a plurality of light-emitting elements are arranged at predetermined intervals to provide a uniform surface light source. An emission wavelength may be set to a visible light region or a near-infrared region and is selected according to a detection characteristic of a camera and a light transmission characteristic of a target cell.

Accordingly, a panel being transferred by the vision align stage 600 can perform vision inspection using a lower light source (the backlight 605) in a stopped state, and when a defect is detected, a cell string replacement or rearrangement operation is precisely performed.

Meanwhile, a vision align robot 700 illustrated in FIG. 7 is installed on the vision align stage 600 and is configured to perform removal, replacement, and rearrangement of cell strings in a solar panel manufacturing process.

The vision align robot 700 includes a multi-degree-of-freedom robot arm 701, and a gripper 702 is mounted at an end of the robot arm 701. The gripper 702 is provided with a plurality of vacuum pads 703 to adsorb and grasp a cell string, and the vacuum pads 703 are arranged in a dispersed manner to provide uniform adsorption force to a cell surface. The vacuum pads 703 are formed of a soft material to suppress damage to the cell surface, driven by a vacuum generator and a control valve, and adsorption is checked in real time through a pressure sensor.

A vision camera module 704 is mounted on the robot arm 701 to capture an arrangement state of the cell strings or reference marks, and a captured image is transmitted to an information processing device to detect a position error or a rotation error of the cell strings. Correction coordinates calculated by the vision camera module 704 are reflected in control of the robot arm 701 so that removal and rearrangement operations of the cell strings are precisely performed.

Movement of the robot arm 701 is guided by a guide rail 705, thereby securing a working range capable of covering the entire vision align stage 600. A power line, signal line, and vacuum line connected to the robot arm 701 are accommodated in a cable housing 706 and are not exposed to the outside, thereby preventing interference or twisting during movement.

The vision align robot 700 configured as described above can perform the method illustrated in FIG. 4. Specifically, in a state in which the conveyor belt 602 is stopped, the vision camera module 704 detects an alignment state of the cell strings using transmitted light irradiated by the backlight 605, and removes a defective cell string by adsorbing it with the vacuum pads 703.

At this time, in a process of performing EL inspection, the vision align robot 700 may receive from the information processing device information regarding a defect detected by analysis of an image captured in the EL inspection, for example, information regarding a position of a defective cell string. Accordingly, the vision align robot 700 can identify and remove the defective cell string.

Thereafter, the vision camera module 704 senses existence of foreign substances in an area into which a new cell string is to be input, and after it is determined that no foreign substance is present or detected foreign substances are removed, a new cell string is input. The robot arm 701 picks up a new cell string from an external supply source using the vacuum pads 703 of the gripper 702, rearranges it based on vision align correction coordinates, and in this process, inclination and position error of the cell string are corrected in real time.

Accordingly, the vision align robot 700 can reduce dependence on manual work and increase alignment accuracy by automating a cell string replacement and rearrangement process, and after replacement, only panels confirmed to be in a normal state through an EL re-inspection process are transferred to a subsequent bus bar joining process.

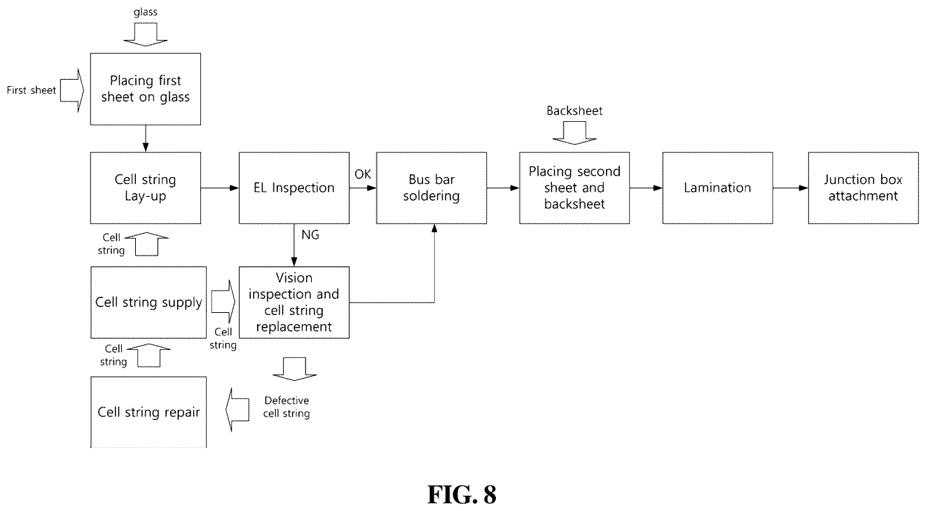

Meanwhile, referring to FIG. 8, a cell string repair line can be additionally arranged selectively in the production line illustrated in FIG. 5. Here, a cell string repair process is a process for repairing a defective cell string, and may be performed using a solar cell repair device including a heating unit as described in Korean Registered Patent No. 10-2726503. The heating unit includes a housing, a plurality of air heaters, and a heating block, and by locally jetting air heated by the air heater through an inlet and an injection port of the heating block, selectively heats an electrode connection part of the defective cell string. By locally heating the electrode connection part in this manner, a defective connection can be released without damaging the cell string, and pretreatment for a new connection is facilitated.

The repair block may further include a cutting unit for cutting wiring of the defective cell string, an alignment unit for precisely positioning a new cell string with respect to remaining wiring, and a soldering device for forming a new connection. If necessary, an inspection device is further provided to check a connection state of the repaired cell string.

For example of an equipment configuration in the “cell string repair” block, as a transfer device for transferring a cell string determined to be defective to a repair area, a robot handler may be separately provided, or the vision align robot 700 described above may pick up a defective cell string and drop it on a transfer tray.

Meanwhile, in the cell string repair process, as described above, a repair device including a heating means may be used, and such a repair device may include, together with the heating unit described above, a cutting unit, an alignment unit, and a soldering device.

At this time, in the EL inspection block, a defect position or a type of defect of the cell string captured by the infrared camera can be precisely detected, and the precisely detected defect position or type of defect can be transmitted to a controller (not shown) of the repair device including the heating unit. Accordingly, in the repair device, an electrode portion to be heated, a wiring cutting portion, and a cell to be replaced can be identified.

Thereafter, a repaired cell string is transferred to a cell string supply block. The cell string supply block may be provided at a front end of the production line and may supply repaired cell strings to the production line in the same flow as new cell strings. Specifically, the repaired cell string may be selectively supplied to the cell string lay-up block or the vision inspection and cell string replacement block, or may be supplied to the vision inspection and cell string replacement block. Accordingly, the repaired cell string is arranged on the first sheet in the same manner as a new cell string, or is input as a material for replacing a defective cell string by the vision align apparatus.

Therefore, according to the present embodiment, since a defective cell string is not simply discarded, but is repaired in the repair block and then reused again through the supply block, material waste can be reduced and manufacturing efficiency can be improved.

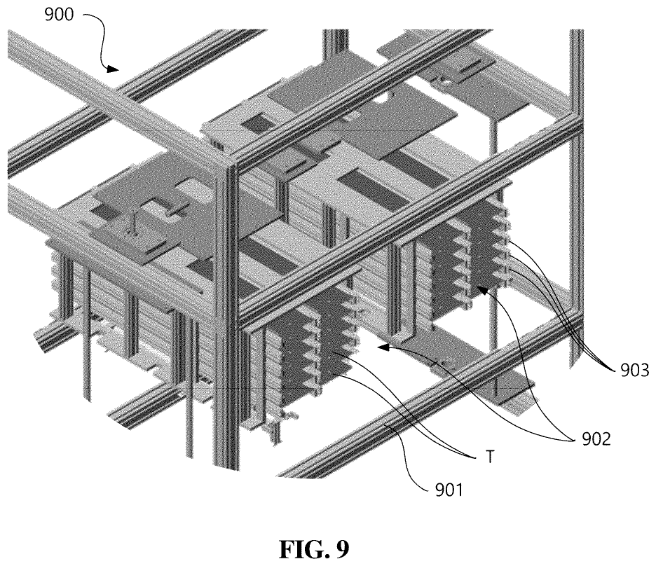

Particularly, here, the cell string supply block may be implemented as a cell string supply apparatus 900 as illustrated in FIG. 9. FIG. 9 is a diagram illustrating a cell string supply equipment applied to a production line according to a solar panel manufacturing method of the embodiment illustrated in FIG. 5 or the other embodiment illustrated in FIG. 8.

Referring to FIG. 9, a cell string supply apparatus 900 according to an embodiment stores a plurality of cell strings in a stacked state and automatically supplies them to a production line when necessary.

The cell string supply apparatus 900 is basically supported by a frame 901. The frame 901 secures structural rigidity of the entire apparatus and serves as a support for stably fixing a tray stacking part 902 and a stacking guide 903.

In the frame 901, the tray stacking part 902 is disposed. The tray stacking part 902 provides a space for storing a plurality of trays stacked in a vertical direction, and pre-prepared cell strings are stored in each tray.

The stacking guide 903 guides positions of the trays so that when the trays are stacked in multiple stages, the trays are stably stacked in alignment. Through this, tilting or misalignment of the trays is prevented, and damage or transfer failure of the cell strings can be suppressed.

Accordingly, based on the frame 901, the cell string supply apparatus 900 can stably supply cell strings to a lay-up device or a vision inspection and replacement block by storing a plurality of cell strings in the tray stacking part 902 and maintaining the stacked state aligned by the stacking guide 903.

Describing, by way of example, a structure for sequentially supplying trays placed in the cell string supply apparatus 900, although not illustrated in the drawings, a guide supporting a lowermost tray among the stacking guides 903 that support the trays may rotate to release support for the lowermost tray so that the tray descends in a gravity direction and is seated on a conveyor belt (not shown). Alternatively, as another embodiment, a pusher arm for pushing the tray toward the conveyor belt may be provided.

In this manner, while the cell string supply apparatus 900 stores or transports trays in a stacked state in which one or more cell strings are stored, by supplying the trays onto the conveyor belt, cell strings can be automatically supplied smoothly in a cell string lay-up or a cell string replacement process.

Meanwhile, in the above embodiments, although only the EL inspection is mainly described in inspection at a cell string unit or inspection at a solar panel unit, in inspection at a cell string unit, a vision inspection, a soldering quality inspection, an electrical continuity inspection, and a string EL inspection may be performed, and in inspection at a solar panel unit, an optical inspection, an insulation withstand voltage inspection, an IV characteristic inspection, and a final EL inspection may be performed.

Particularly, in one embodiment, a string-unit EL inspection and a final panel-unit EL inspection may be replaced with a single integrated EL inspection before bus bar connection, and in another embodiment, after a string-unit EL inspection is performed, the final panel-unit EL inspection may be brought forward to be performed before bus bar connection.

In the conventional field, after first filtering out cracks or soldering defects through EL inspection at a cell string unit at an outlet of a stringer, a cell string lay-up and bus bar soldering were performed, and a final panel-unit EL inspection was again performed before and after lamination. However, when a defect of a cell string is detected after bus bar soldering or lamination is performed, replacement of the cell string is substantially difficult, so there was a problem that inspection efficiency is low.

Therefore, as described above, by performing the panel-unit EL inspection before bus bar soldering, defects at a cell string unit and defects at a panel unit can be detected at once, and cell string replacement or repair can be performed, thereby obtaining an effect of greatly improving productivity.

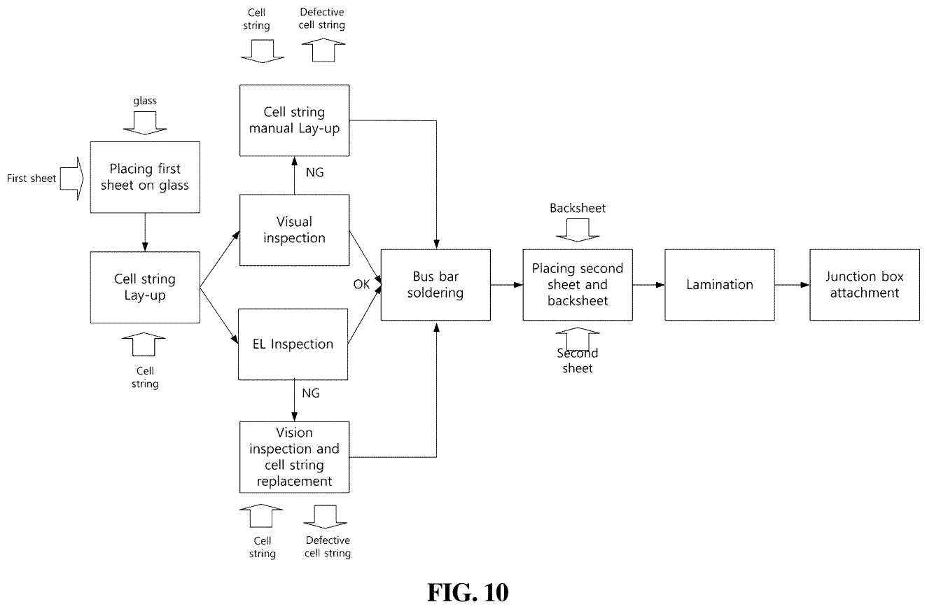

Meanwhile, according to another embodiment, in the embodiments of the production line illustrated in FIGS. 5 and 8, an inspection process may be divided into an EL inspection block and a visual inspection block, respectively. FIG. 10 is a diagram illustrating an example of a production line layout according to a solar panel manufacturing method of another embodiment.

Referring to FIG. 10, two inspection blocks may be arranged in the production line. A solar panel on which cell strings are arranged may be preferentially supplied to the EL block among the two inspection blocks, but for reasons such as throughput saturation or device abnormality of the EL inspection block, the solar panel on which cell strings are arranged may be supplied to the visual inspection block. That is, the visual inspection block may be used as an auxiliary.

Meanwhile, a panel in which a defective cell string is detected as a result of EL inspection may be transferred to the vision inspection and cell string replacement block as in other embodiments. Meanwhile, a panel in which a defective cell string is detected as a result of visual inspection may be transferred to a manual lay-up block in a state in which a defect position is manually marked, and the defective cell string may be replaced by a worker. Alternatively, depending on the embodiment, all cell strings may be replaced by returning again to the cell string lay-up block.

Also in the embodiment of FIG. 10, one or more repair blocks of removed defective cell strings may be arranged so that cell string repair is performed in parallel.

The term “-unit” used in the above embodiments means a hardware component such as software, an FPGA (field programmable gate array) or an ASIC, and the “-unit” performs certain roles. However, the “-unit” is not limited to software or hardware. The “-unit” may be configured to be in an addressable storage medium and configured to reproduce one or more processors. Therefore, as an example, the “-unit” includes software components, object-oriented software components, class components, and task components, as well as components such as processes, functions, attributes, procedures, subroutines, segments of program patent code, drivers, firmware, microcode, circuits, data, databases, data structures, tables, arrays, and variables.

Functions provided within components and “-units” may be combined into a smaller number of components and “-units” or may be separated from additional components and “-units.”

In addition, components and “-units” may be implemented to reproduce one or more CPUs in a device or a secure multimedia card.

Some steps of the solar panel manufacturing method according to the embodiments described with reference to FIGS. 2 to 10 may also be implemented in the form of a computer-readable medium storing instructions and data executable by a computer. At this time, the instructions and data may be stored in the form of program code, and when executed by a processor, may generate a predetermined program module to perform a predetermined operation. In addition, a computer-readable medium may be any available medium accessible by a computer, and includes both volatile and non-volatile media and both removable and non-removable media. In addition, the computer-readable medium may be a computer recording medium, and the computer recording medium may include both volatile and non-volatile media and both removable and non-removable media implemented by any method or technology for storing information such as computer-readable instructions, data structures, program modules, or other data. For example, the computer recording medium may be a magnetic storage medium such as HDDs and SSDs, an optical recording medium such as CDs, DVDs, and Blu-ray discs, or a memory included in a server accessible through a network.

In addition, some steps of the solar panel manufacturing method according to the embodiments described with reference to FIGS. 2 to 10 may also be implemented as a computer program (or a computer program product) including computer-executable instructions. The computer program includes programmable machine instructions processed by a processor and may be implemented in a high-level programming language, an object-oriented programming language, an assembly language, or a machine language. The computer program may be recorded on a tangible computer-readable recording medium (for example, a memory, a hard disk, a magnetic/optical medium, or an SSD (Solid-State Drive), etc.).

Therefore, some steps of the solar panel manufacturing method according to the embodiments described with reference to FIGS. 2 to 10 may be implemented by a computing device executing the computer program as described above. The computing device may include at least some of a processor, a memory, a storage device, a high-speed interface connected to the memory and a high-speed expansion port, and a low-speed interface connected to a low-speed bus and the storage device. Each of these components is connected to each other using various buses, and may be mounted on a common motherboard or mounted in other appropriate ways.

Here, the processor can process instructions in the computing device. Such instructions include, for example, instructions stored in the memory or the storage device to display graphic information for providing a GUI (Graphic User Interface) on an external input/output device such as a display connected to the high-speed interface. In another embodiment, a plurality of processors and/or a plurality of buses may be used appropriately together with a plurality of memories and memory types. The processor may be implemented as a chipset formed of chips including a plurality of independent analog and/or digital processors.

In addition, the memory stores information in the computing device. For example, the memory may be configured as a volatile memory unit or a set thereof. In another example, the memory may be configured as a non-volatile memory unit or a set thereof. The memory may also be another form of a computer-readable medium, such as a magnetic or optical disk.

The storage device can provide a large storage space to the computing device. The storage device may be or include a computer-readable medium, and may include, for example, devices in a SAN (Storage Area Network) or other configurations, and may be a floppy disk device, a hard disk device, an optical disk device, or a tape device, a flash memory, another similar semiconductor memory device, or a device array.

The above-described embodiments are illustrative, and those skilled in the art to which the above-described embodiments belong will understand that various modifications can be made in other specific forms without changing the technical spirit or essential characteristics of the above-described embodiments. Therefore, the above-described embodiments are to be understood as illustrative and non-limiting in all respects. For example, each component described as being single may be implemented in a distributed manner, and likewise, components described as being distributed may be implemented in a combined form.

What is claimed is:

1. A solar panel manufacturing method, comprising:
placing a first sheet on a glass substrate;
arranging a plurality of cell strings on the first sheet placed on the glass substrate;
performing an inspection for the arranged plurality of cell strings to detect a defective cell string;
replacing the defective cell string with a new cell string when the defective cell string is detected; and
joining bus bars for electrically connecting the plurality of cell strings, and sequentially placing a second sheet and a backsheet.

2. The solar panel manufacturing method of claim 1, wherein the replacing the defective cell string with a new cell string comprises:
removing the defective cell string;
performing a foreign substance inspection on an area from which the defective cell string has been removed; and
arranging the new cell string in the area from which the defective cell string has been removed when no foreign substance is detected.

3. The solar panel manufacturing method of claim 2, wherein the detecting the defective cell string comprises performing an EL (Electroluminescence) inspection for the arranged plurality of cell strings, and the removing the defective cell string to the arranging the new cell string are performed based on machine vision.

4. The solar panel manufacturing method of claim 1, wherein the new cell string is a normal cell string in which no defect is detected in a pre-inspection at a string unit, and after the replacing with the new cell string, sequentially placing the second sheet and the backsheet on the plurality of cell strings is performed.

5. The solar panel manufacturing method of claim 1, wherein after the replacing with the new cell string, the detecting the defective cell string is performed again.

6. The solar panel manufacturing method of claim 2, further comprising repairing the defective cell string removed in the removing the defective cell string, wherein the repairing comprises:
heating an electrode portion of a defective cell included in the defective cell string to release a connection between the electrode of the defective cell and wiring;
cutting the wiring whose connection with the electrode is released to separate the defective cell from the defective cell string;
replacing the separated defective cell with a replacement cell; and
joining wiring between the replacement cell and an adjacent cell to electrically connect them to form a string.

7. The solar panel manufacturing method of claim 6, wherein the replacing comprises inputting the cell string repaired in the repairing as the new cell string.

8. The solar panel manufacturing method of claim 6, wherein the detecting the defective cell string comprises detecting a position of the defective cell included in the defective cell string, and the repairing is performed with reference to the position of the defective cell detected in the detecting the defective cell string.

9. A solar panel manufacturing apparatus for performing the solar panel manufacturing method according to claim 1, comprising a vision align apparatus which performs the detecting the defective cell string and includes a vision align stage and a vision align robot, wherein the vision align stage comprises:
a conveyor belt that supports and transfers a panel in which the plurality of cell strings are arranged;
a plurality of pulleys which are arranged to cross up and down to transfer the conveyor belt such that a section in which the conveyor belt supports the panel and a section in which the conveyor belt is spaced downward and does not support the panel are alternately formed; and
a backlight disposed in the section in which the conveyor belt is spaced downward and does not support the panel, to irradiate light upward from a lower surface of the panel.

10. The solar panel manufacturing apparatus of claim 9, comprising an information processing device that detects the defective cell string by analyzing an image captured by performing EL inspection, wherein the vision align robot comprises:
a robot arm that removes the defective cell string from the panel based on position information of the defective cell string received from the information processing device, and arranges a new cell string in an area from which the defective cell string has been removed; and
a vision camera module that captures the panel and detects a position of the plurality of cell strings arranged on the panel.
